(19) United States
(12) Patent Application Publication
(10) Pub. No.: US 2025/0088171 A1
(43) Pub. Date: Mar. 13, 2025

(54) METHOD OF MANUFACTURING VIBRATOR ELEMENT, VIBRATOR ELEMENT, AND VIBRATOR

(71) Applicant: SEIKO EPSON CORPORATION, Tokyo (JP)

(72) Inventors: Keiichi Yamaguchi, Ina-shi (JP); Atsushi Matsuo, Shiojiri-shi (JP); Ryuta Nishizawa, Nagano-shi (JP); Shigeru Shiraishi, Ina-shi (JP)

(21) Appl. No.: 18/956,139

(22) Filed: Nov. 22, 2024

Related U.S. Application Data
(62) Division of application No. 17/232,510, filed on Apr. 16, 2021.

(30) Foreign Application Priority Data
Apr. 24, 2020 (JP) 2020-077202

(51) Int. Cl. H03H 9/10; H03H 3/02; H03H 9/19

(52) U.S. Cl. CPC H03H 9/1021; H03H 3/02; H03H 9/19

(57) ABSTRACT

A method of manufacturing a vibrator element having a vibrating part which vibrates in a thickness-shear mode, and a thin-wall part which is coupled to the vibrating part, and which is thinner than the vibrating part includes a preparation step of preparing a quartz crystal substrate, a resist film formation step of forming a resist film in a vibrating part area of the quartz crystal substrate where the vibrating part is formed, an etching step of etching the quartz crystal substrate via the resist film, then ending the etching in a state in which the resist film remains in the vibrating part area to thereby form the vibrating part and the thin-wall part, and a resist film removal step of removing the resist film remaining.

The present application is a divisional application claiming priority to U.S. application Ser. No. 17/232,510, filed Apr. 16, 2021, the disclosure of which is hereby incorporated by reference herein in its entirety.

The present application is also based on, and claims priority from JP Application Serial Number 2020-077202, filed Apr. 24, 2020, the disclosure of which is hereby incorporated by reference herein in its entirety.

### BACKGROUND

### 1. Technical Field

The present disclosure relates to a method of manufacturing a vibrator element, a vibrator element, and a vibrator.

### 2. Related Art

In JP-A-2005-244677 (Document 1), there is described a convex processing method of shaping the principal surface of a quartz crystal vibrating plate into a convex shape. Such a convex processing method includes a step of forming a resist film, which is etched in the same condition as that of a quartz crystal, and has a convex shape, on the quartz crystal plate, and a step of performing dry etching via a resist. Further, in the step of the dry etching, the resist film disappears during the dry etching, and the convex shape of the resist film is transferred to a principal surface of the quartz crystal plate. Thus, the principal surface of the quartz crystal plate is provided with the convex shape.

However, in such a convex processing method, the principal surface of the quartz crystal plate is formed of a dry-etched surface. The dry-etched surface is apt to be coarse depending on unevenness of the thickness of the resist film. Therefore, the surface roughness of the principal surface of the quartz crystal plate is apt to be high. Further, due to the roughness of the principal surface, unevenness of the thickness of the quartz crystal vibrating plate occurs to fail to obtain a desired drive frequency, or it becomes easy for a spurious vibration, which is an unwanted vibration other than the thickness-shear vibration as the principal vibration, to occur. Therefore, in the convex processing method in Document 1, there is a problem that deterioration of the vibration characteristics occurs.

### SUMMARY

A method of manufacturing a vibrator element according to the present disclosure is a method of manufacturing a vibrator element having a vibrating part which vibrates in a thickness-shear mode, and a thin-wall part which is coupled to the vibrating part, and which is thinner than the vibrating part, the method including a preparation step of preparing a quartz crystal substrate, a resist film formation step of forming a resist film in a vibrating part area of the quartz crystal substrate where the vibrating part is formed, an etching step of etching the quartz crystal substrate via the resist film, then ending the etching in a state in which the resist film remains in the vibrating part area to thereby form the vibrating part and the thin-wall part, and a resist film removal step of removing the resist film remaining.

A vibration element according to the present disclosure includes a vibrating part which vibrates in a thickness-shear mode, and a thin-wall part which is coupled to the vibrating part, and which is thinner than the vibrating part, wherein surface roughness of a principal surface of the vibrating part is lower than surface roughness of a principal surface of the thin-wall part.

A vibrator according to the present disclosure includes the vibrator element described above, and a package configured to house the vibrator element.

### BRIEF DESCRIPTION OF THE DRAWINGS

FIG. 1 is a plan view showing a vibrator element according to a first embodiment of the present disclosure.

FIG. 2 is a diagram showing a cutting angle of AT cut.

FIG. 3 is a cross-sectional view along the line A-A in FIG. 1.

FIG. 4 is a cross-sectional view along the line B-B in FIG. 1.

FIG. 5 is a cross-sectional view showing a modified example of the vibrator element.

FIG. 6 is a cross-sectional view showing a modified example of the vibrator element.

FIG. 7 is a flowchart showing a manufacturing process of the vibrator element.

FIG. 8 is a cross-sectional view for explaining a method of manufacturing the vibrator element.

FIG. 9 is a cross-sectional view for explaining the method of manufacturing the vibrator element.

FIG. 10 is a flowchart showing a resist film formation step.

FIG. 11 is a cross-sectional view for explaining the method of manufacturing the vibrator elements.

FIG. 12 is a cross-sectional view for explaining the method of manufacturing the vibrator elements.

FIG. 13 is a cross-sectional view for explaining the method of manufacturing the vibrator elements.

FIG. 14 is a cross-sectional view for explaining the method of manufacturing the vibrator elements.

FIG. 15 is a plan view for explaining the method of manufacturing the vibrator element.

FIG. 16 is a flowchart showing a manufacturing process of a vibrator element according to a second embodiment of the present disclosure.

FIG. 17 is a cross-sectional view for explaining a method of manufacturing the vibrator elements.

FIG. 18 is a cross-sectional view for explaining the method of manufacturing the vibrator elements.

FIG. 19 is a cross-sectional view showing a vibrator element according to a third embodiment of the present disclosure.

FIG. 20 is a cross-sectional view showing the vibrator element according to the third embodiment of the present disclosure.

FIG. 21 is a cross-sectional view showing a modified example of the vibrator element.

FIG. 22 is a cross-sectional view showing the modified example of the vibrator element.

FIG. 23 is a cross-sectional view showing a vibrator element according to a fourth embodiment of the present disclosure.

FIG. 24 is a cross-sectional view showing the vibrator element according to the fourth embodiment of the present disclosure.

FIG. 25 is a cross-sectional view for explaining a method of manufacturing the vibrator elements.

FIG. 26 is a cross-sectional view for explaining the method of manufacturing the vibrator elements.

FIG. 27 is a cross-sectional view for explaining the method of manufacturing the vibrator elements.

FIG. 28 is a cross-sectional view showing a vibrator according to a fifth embodiment of the present disclosure.

### DESCRIPTION OF EXEMPLARY EMBODIMENTS

A method of manufacturing a vibrator element, a vibrator element, and a vibrator according to the present disclosure will hereinafter be described in detail based on some embodiments shown in the accompanying drawings.

### First Embodiment

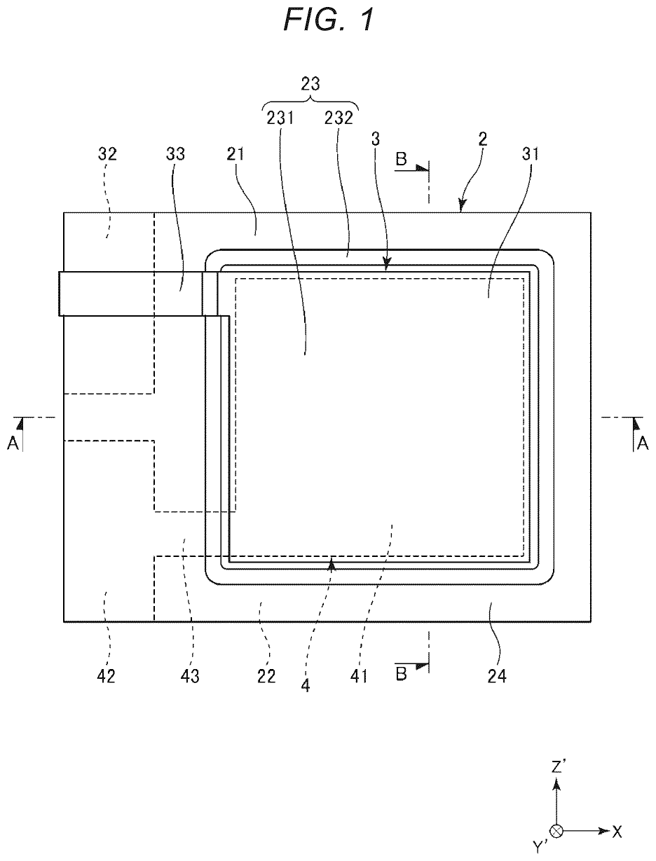

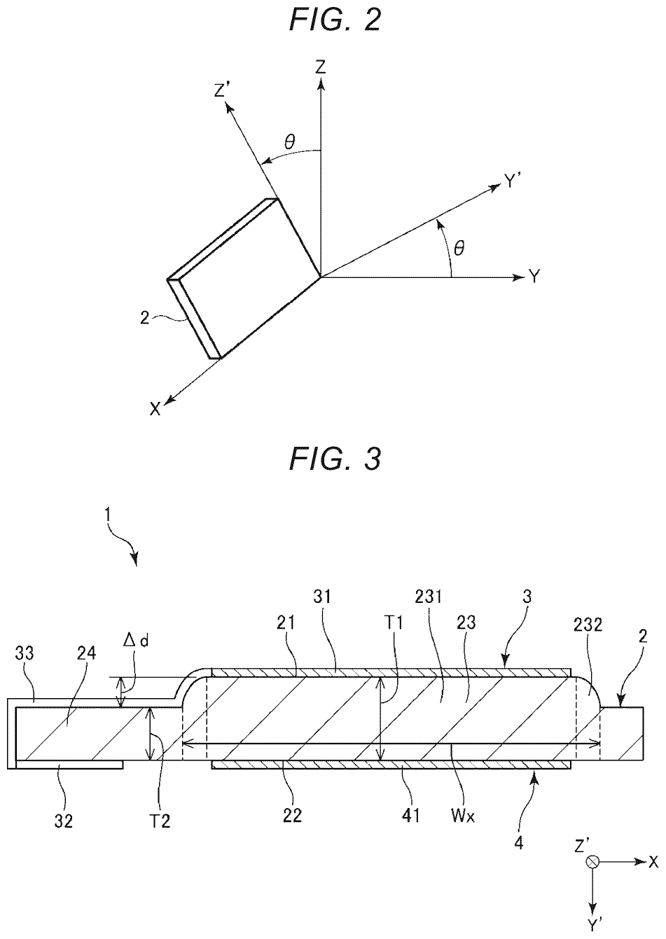

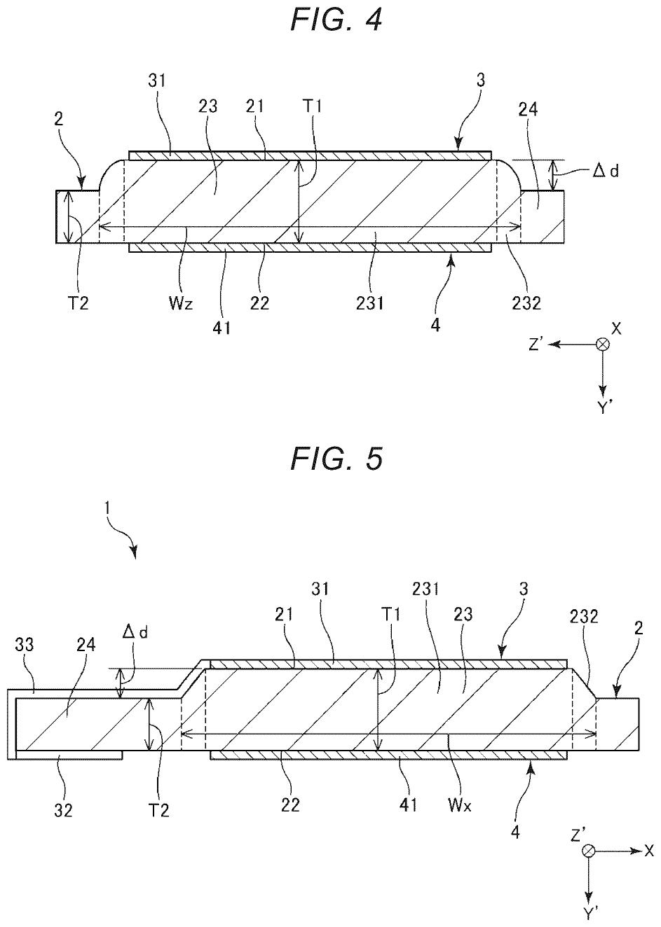

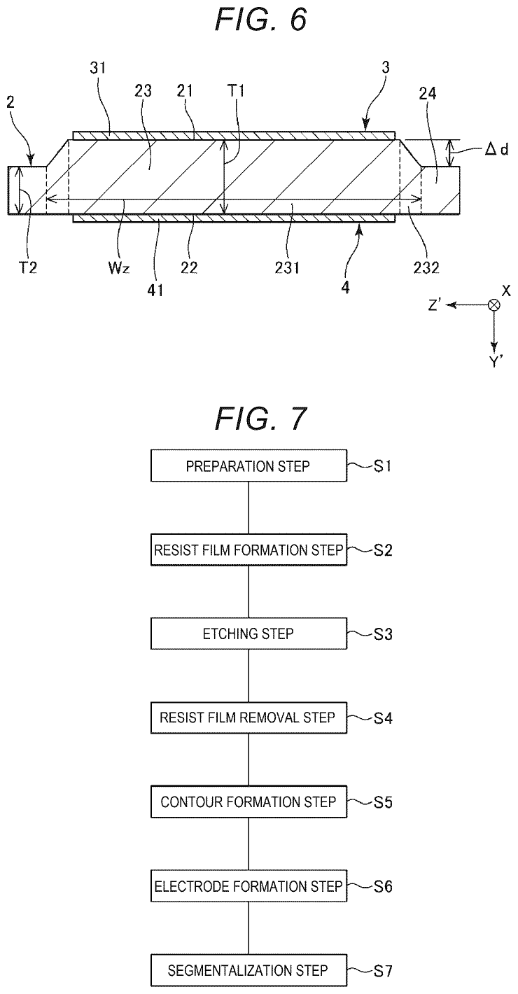

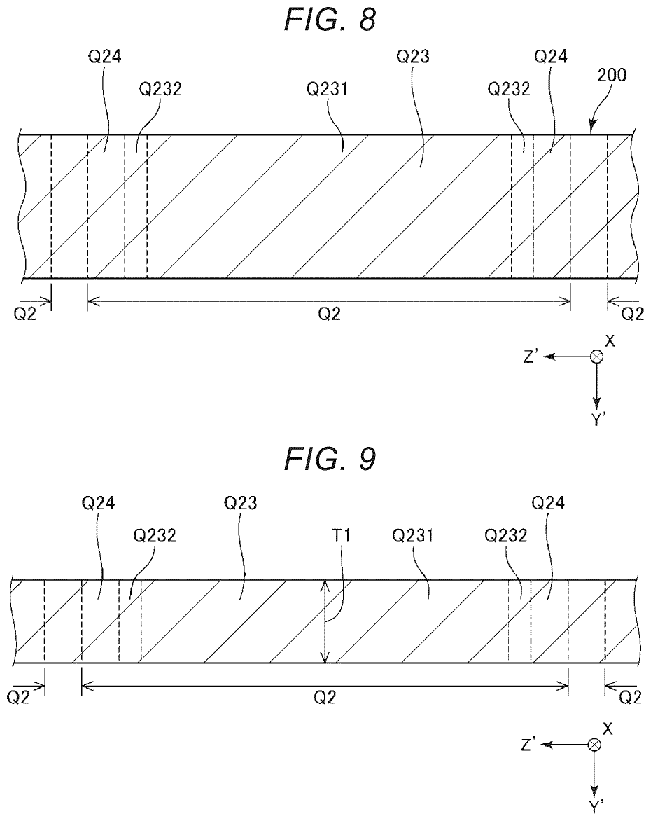

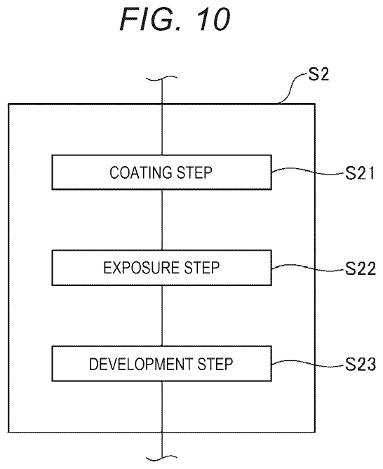

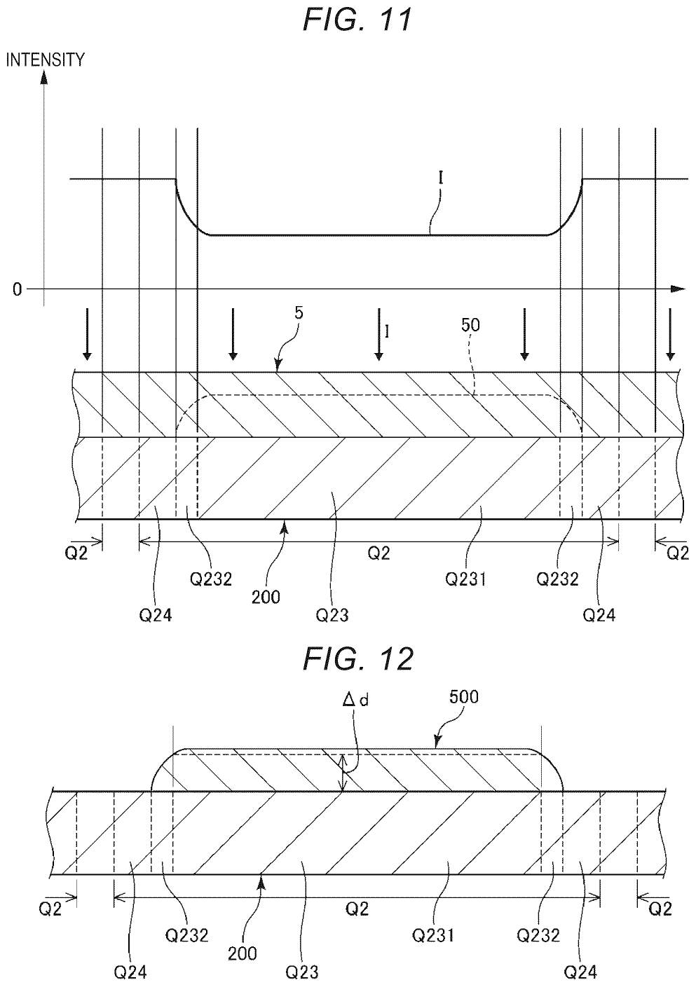

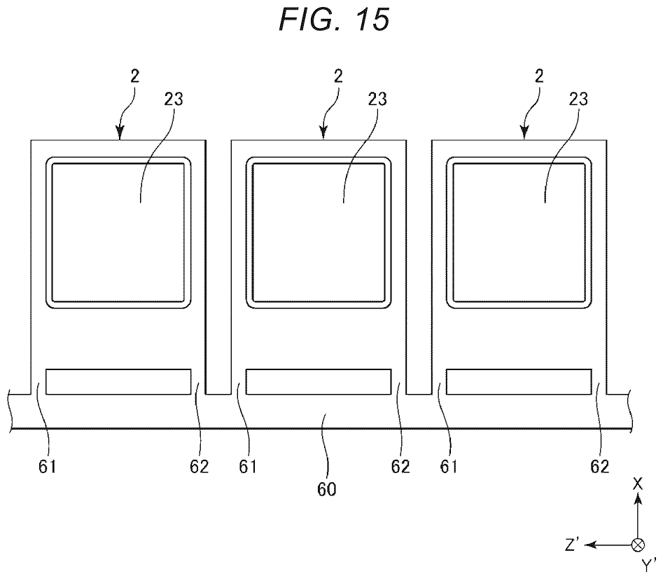

FIG. 1 is a plan view showing a vibrator element according to a first embodiment of the present disclosure. FIG. 2 is a diagram showing a cutting angle of AT cut. FIG. 3 is a cross-sectional view along the line A-A in FIG. 1. FIG. 4 is a cross-sectional view along the line B-B in FIG. 1. FIG. 5 and FIG. 6 are each a cross-sectional view showing a modified example of the vibrator element. FIG. 7 is a flowchart showing a manufacturing process of the vibrator element. FIG. 8 and FIG. 9 are each a cross-sectional view for explaining a method of manufacturing the vibrator element. FIG. 10 is a flowchart showing a resist film formation step. FIG. 11 through FIG. 14 are cross-sectional views for explaining the method of manufacturing the vibrator elements. FIG. 15 is a plan view for explaining the method of manufacturing the vibrator elements.

A vibrator element 1 shown in FIG. 1 is an AT-cut quartz crystal vibrator element. The vibrator element 1 has a quartz crystal substrate 2 as an AT-cut quartz crystal substrate, and a pair of electrodes 3, 4 provided to the quartz crystal substrate 2. The quartz crystal substrate 2 as an AT-cut quartz crystal substrate has a thickness-shear vibration mode, and has a third-order frequency-temperature characteristic. Therefore, the vibrator element 1 has an excellent temperature characteristic. It should be noted that the quartz crystal substrate 2 is not limited to the AT-cut quartz crystal substrate providing the quartz crystal substrate 2 has the thickness-shear vibration mode as a principal vibration.

The AT cut will briefly be described. As shown in FIG. 2, quartz crystal has crystal axes X, Y, and Z perpendicular to each other. The X axis, the Y axis, and the Z axis are called an electrical axis, a mechanical axis, and an optical axis, respectively. The quartz crystal substrate 2 is a “rotated Y-cut quartz crystal substrate” carved out along a plane obtained by rotating the X-Z plane around the X axis as much as a predetermined angle θ, and the substrate which is carved out along a plane obtained by the rotation as much as θ=35°15′ is called an “AT-cut quartz crystal substrate.” It should be noted that the Y axis and the Z axis rotated around the X axis in accordance with the angle θ are hereinafter referred to as a Y′ axis and a Z′ axis, respectively. In other words, the quartz crystal substrate 2 has a thickness in a direction along the Y′ axis, and spread in a direction along the X-Z′ plane. Further, the length in a direction along the Y′ axis is hereinafter referred to also as a “thickness.” Further, the tip side of the arrow of each of the axes is also referred to as a “positive side,” and the opposite side is also referred to as a “negative side.” Further, the positive side of the Y′ axis is also referred to as a “lower side,” and the negative side thereof is also referred to as an “upper side.”

Further, the quartz crystal substrate 2 is a thin plate, and has an upper surface 21 and a lower surface 22 as principal surfaces having an obverse-reverse relationship with each other. Further, the planar shape of the quartz crystal substrate 2 is a rectangular shape. In particular, in the present embodiment, the planar shape is an oblong having long sides in a direction along the X axis, and having short sides in a direction along the Z′ axis. It should be noted that this is not a limitation, and the quartz crystal substrate 2 can have an elongated shape having the short sides in a direction along the X axis and the long sides in a direction along the Z′ axis, or can also have a square shape.

Further, as shown in FIG. 3 and FIG. 4, the quartz crystal substrate 2 has a vibrating part 23 vibrating in the thickness-shear mode, and a thin-wall part 24 disposed so as to surround the periphery of the vibrating part 23. Further, the quartz crystal substrate 2 is of a mesa type, and a thickness T1 of the vibrating part 23 is thicker than a thickness T2 of the thin-wall part 24. Further, the vibrating part 23 projects only toward the negative side of the Y′ axis from the thin-wall part 24. In other words, the upper surface 21 in the vibrating part 23 projects toward the negative side of the Y′ axis from the upper surface 21 in the thin-wall part 24, and the lower surface 22 in the vibrating part 23 is made coplanar with the lower surface 22 in the thin-wall part 24, namely forms a continuous flat surface with the lower surface 22 in the thin-wall part 24. By adopting such a mesa type quartz crystal substrate 2, it is possible to effectively confine the thickness-shear vibration caused in the vibrating part 23 in the vibrating part 23. Therefore, the vibration leakage can effectively be suppressed to obtain the vibrator element 1 having excellent vibration characteristics. It should be noted that a shift amount in a direction along the Y′ axis between the upper surface 21 in the vibrating part 23 and the upper surface 21 in the thin-wall part 24 is hereinafter defined as a separation distance Δd for the sake of convenience of explanation.

Further, the vibrating part 23 has a central portion 231 which overlaps a flat portion of the upper surface 21, and an outer edge portion 232 which is located on the periphery of the central portion 231 to couple the central portion 231 and the thin-wall part 24 to each other. The outer edge portion 232 has a taper shape, and a width Wx in a direction along the X axis and a width Wz in a direction along the Z′ axis each gradually increase from the upper surface 21 in the vibrating part 23 toward the upper surface 21 in the thin-wall part 24. Further, increment ratios of the width Wx and the width Wz each gradually decrease from the upper surface 21 in the vibrating part 23 toward the upper surface 21 in the thin-wall part 24. Therefore, the contour of the outer edge portion 232 curved convexly in each of the cross-sectional view from a direction along the X axis and the cross-sectional view from a direction along the Z′ direction. By providing the outer edge portion 232 with the taper shape as described above, the confinement effect of the thickness-shear vibration is enhanced. In other words, the thickness-shear vibration generated in the vibrating part 23 can more effectively be confined in the vibrating part 23. Therefore, the vibration leakage can more effectively be suppressed to obtain the vibrator element 1 having more excellent vibration characteristics.

It should be noted that the shape of the outer edge portion 232 is not particularly limited, and can be provided with a taper shape in which the increment ratios of the width Wx and the width Wz are each constant, and which is formed of a flat surface as shown in, for example, FIG. 5 and FIG. 6.

Further, a surface roughness R1 of the upper surface 21 and the lower surface 22 in the vibrating part 23 is lower than a surface roughness R2 of the upper surface 21 in the thin-wall part 24. In other words, R1<R2 is true. Thus, the upper surface 21 and the lower surface 22 in the vibrating part 23 each become a surface sufficiently low in surface roughness, namely a flat surface, and it becomes difficult for a spurious vibration which is an unwanted vibration other than the thickness-shear vibration as the principal vibration to be generated in the vibrating part 23. Therefore, there is obtained the vibrator element 1 having excellent vibration characteristics. In contrast, since the surface roughness R2 of the thin-wall part 24 which hardly affects the vibration characteristics is allowed to be high, the number of choices for the formation measure of the thin-wall part 24 increases, and further, the surface treatment for decreasing the surface roughness R2 becomes unnecessary. Therefore, it becomes easy to form the quartz crystal substrate 2. It should be noted that the surface roughness R1, R2 is not particularly limited, and it is possible to use, for example, arithmetic mean roughness Ra or maximum height Rz, but in the specification of the present disclosure, there is used the arithmetic mean roughness Ra.

The surface roughness R1 (μm) is not particularly limited, but is preferably, for example, no higher than 1×10⁻³, more preferably no higher than 0.5×10⁻³, and further more preferably no higher than 0.2×10⁻³. Thus, the upper surface 21 and the lower surface 22 in the vibrating part 23 each become a smoother surface, namely a mirror surface, and it becomes more difficult for the unwanted vibration to be generated in the vibrating part 23. Therefore, there is obtained the vibrator element 1 having more excellent vibration characteristics.

It should be noted that the surface roughness R1 of both of the upper surface 21 and the lower surface 22 in the vibrating part 23 is lower than the surface roughness R2 of the upper surface 21 in the thin-wall part 24 in the present embodiment, but this is not a limitation, and it is sufficient for the surface roughness R1 of at least one of the upper surface 21 and the lower surface 22 in the vibrating part 23 to be lower than the surface roughness R2 of the upper surface 21 in the thin-wall part 24.

Such a quartz crystal substrate 2 can be obtained by preparing a quartz crystal substrate 200 which is polished to be adjusted into the thickness T1, and which is planarized in the upper and lower surfaces, and then reducing the thickness of the periphery of the vibrating part 23 using dry etching from the upper surface side to form the thin-wall part 24 as described later. Therefore, the upper surface 21 and the lower surface 22 in the vibrating part 23 and the lower surface 22 in the thin-wall part 24 are not dry-etched and remain as polished surfaces, and the upper surface 21 in the thin-wall part 24 turns to an etched surface formed by the dry etching.

By leaving the upper surface 21 and the lower surface 22 in the vibrating part 23 as the polished surfaces as described above, there is no chance for the surface roughness R1 which have been made sufficiently low by polishing to be deteriorated by the dry etching, and increase in surface roughness, or to increase in variation. Therefore, even after the dry etching, it is possible to keep the surface roughness R1 sufficiently low. Further, even after the dry etching, it is possible to keep the vibrating part 23 in the thickness T1. Therefore, it is also possible to suppress the shift in oscillation frequency due to the dry etching. On the other hand, by forming the upper surface 21 in the thin-wall part 24 from the etched surface, namely by forming the thin-wall part 24 using the dry etching, it becomes easy to form the quartz crystal substrate 2.

It should be noted that as long as R1<R2 is fulfilled, the method of forming the upper surface 21 and the lower surface 22 in the vibrating part 23, and the method of forming the upper surface 21 and the lower surface 22 in the thin-wall part 24 are not particularly limited. The upper surface 21 and the lower surface 22 in the vibrating part 23, and the lower surface 22 in the thin-wall part 24 are not required to be the polished surface, and the upper surface 21 in the thin-wall part 24 is not required to be the etched surface. For example, the upper surface 21 and the lower surface 22 in the vibrating part 23 can each be a surface which is formed by performing a further planarization process on the polished surface for the purpose of lowering the surface roughness R1.

As shown in FIG. 1 and FIG. 3, the electrode 3 has a first excitation electrode 31, a first terminal 32, and a first coupling interconnection 33, wherein the first excitation electrode 31 is disposed on the upper surface 21 in the vibrating part 23, the first terminal 32 is disposed on the lower surface 22 in the thin-wall part 24, and the first coupling interconnection 33 electrically couples the first excitation electrode 31 and the first terminal 32 to each other. Meanwhile, the electrode 4 has a second excitation electrode 41, a second terminal 42, and a second coupling interconnection 43, wherein the second excitation electrode 41 is disposed on the lower surface 22 in the vibrating part 23 so as to be opposed to the first excitation electrode 31, the second terminal 42 is disposed on the lower surface 22 in the thin-wall part 24, and the second coupling interconnection 43 electrically couples the second excitation electrode 41 and the second terminal 42 to each other.

The vibrator element 1 is hereinabove described. As described above, such a vibrator 1 has the vibrating part 23 which makes the thickness-shear vibration, and the thin-wall part 24 which is coupled to the vibrating part 23 and is thinner than the vibrating part 23. Further, the surface roughness R1 of the upper surface 21 as the principal surface of the vibrating part 23 is lower than the surface roughness R2 of the upper surface 21 as the principal surface of the thin-wall part 24. In other words, R1<R2 is true. Thus, the upper surface 21 in the vibrating part 23 becomes a smoother surface, and it becomes difficult for the unwanted vibration to be generated in the vibrating part 23. Therefore, there is obtained the vibrator element 1 having excellent vibration characteristics. On the other hand, since the surface roughness R2 of the thin-wall part 24 which hardly affects the vibration characteristics is allowed to be higher than the surface roughness R1, the number of choices for the formation measure of the thin-wall part 24 increases, and further, the surface treatment or the like for decreasing the surface roughness R2 becomes unnecessary. Therefore, it becomes easy to form the quartz crystal substrate 2.

Further, as described above, the upper surface 21 in the vibrating part 23 is the polished surface. Thus, it is possible to decrease the surface roughness R1 of the upper surface 21 in the vibrating part 23 with relative ease. Further, as described above, the upper surface 21 in the thin-film part 24 is the etched surface. Thus, it becomes easy to form the thin-wall part 24.

Further, as described above, the outer edge portion 232 of the vibrating part 23 has the taper shape. Thus, the thickness-shear vibration can more effectively be confined in the vibrating part 23. Therefore, there is obtained the vibrator element 1 in which the vibration leakage is suppressed, and which has the excellent vibration characteristics.

Then, a method of manufacturing the vibrator element 1 will be described. As shown in FIG. 7, the method of manufacturing the vibrator element 1 includes a preparation step S1 of preparing the quartz crystal substrate 200 as a parent material of the quartz crystal substrate 2, a resist film formation step S2 of forming a resist film 500 on the quartz crystal substrate 200, an etching step S3 of etching the quartz crystal substrate 200 via the resist film 500 to form the vibrating part 23 and the thin-wall part 24, a resist film removal step S4 of removing the resist film 500 remaining on the quartz crystal substrate 200, a contour formation step S5 of forming a contour of the quartz crystal substrate 2, an electrode formation step S6 of providing the quartz crystal substrate 2 with the electrodes 3, 4, and a segmentalization step S7 of segmentalizing the vibrator element 1.

### Preparation Step S1

First, as shown in FIG. 8, the AT-cut quartz crystal substrate 200 as the parent material of the quartz crystal substrate 2 is prepared. The quartz crystal substrate 200 is a quartz crystal wafer, and is larger than the quartz crystal substrate 2, and it is possible to form a plurality of quartz crystal substrates 2 from the quartz crystal substrate 200. It should be noted that an area which turns to the quartz crystal substrate 2 is hereinafter also referred to as an “element area Q2.” In each of the element areas Q2, there are included a vibrating part area Q23 which turns to the vibrating part 23 in the etching step S3 performed later, and a thin-wall part area Q24 which turns to the thin-wall part 24 in the etching step S3 performed later. Further, in the vibrating part area Q23, there are included a central portion area Q231 which turns to the central portion 231, and an outer edge portion area Q232 which turns to the outer edge portion 232.

Then, a grinding processing for thickness adjustment and planarization is performed on both principal surfaces of the quartz crystal substrate 200. Such grinding processing is also called lapping processing. For example, using a wafer polishing device provided with a pair of surface plates disposed vertically, the quartz crystal substrate 200 is clamped between the surface plates rotating in respective directions opposite to each other to polish the both surfaces of the quartz crystal substrate 200 while rotating the quartz crystal substrate 200 and at the same time supplying a polishing fluid. It should be noted that in the grinding processing, it is possible to perform mirror polishing processing on the both surfaces of the quartz crystal substrate 200 as needed in succession to the lapping processing described above. Such grinding processing is also called polishing processing. Thus, it is possible to provide the both principal surfaces of the quartz crystal substrate 200 with mirrored surfaces. Due to such grinding processing as described above, the both principal surface of the quartz crystal substrate 200 are planarized, and at the same time, the thickness of the quartz crystal substrate 200 is made equal to the thickness T1 of the vibrating part 23. According to such grinding processing, it is possible to lower the surface roughness of the both principal surfaces of the quartz crystal 1 substrate 200 to a sufficiently low level, and at the same time, it is possible to perform the thickness control of the quartz crystal substrate 200 with high accuracy compared to other methods.

### Resist Film Formation Step S2

As shown in FIG. 10, the present step includes a coating step S21 of applying a resist material 5 to the upper surface of the quartz crystal substrate 200, an exposure step S22 of exposing the resist material 5 on the quartz crystal substrate 200, and a development step S23 of developing the resist material 5 on the quartz crystal substrate 200. According to such a method, it is possible to easily form a resist film 500 on the upper surface of the quartz crystal substrate 200. The detailed description will hereinafter be presented. It should be noted that the method of forming the resist film 500 is not particularly limited.

First, the resist material 5 is applied to the upper surface of the quartz crystal substrate 200 with a predetermined thickness. As the resist material 5, there is used a material which is etched in the same condition as that of the quartz crystal in the etching step S3 to be performed later. Then, irradiation with an electromagnetic wave I the exposure intensity of which is varied from the central portion of each of the element areas Q2 toward the outer edge portion using a filter, a mask, or the like is performed to thereby form exposure boundary areas 50 due to presence or absence of the exposure in the resist material 5. FIG. 11 shows an example of a distribution of the exposure intensity in a direction along the Z′ axis.

Subsequently, the resist material 5 is developed. Thus, as shown in FIG. 12, the resist film 500 made of the resist material 5 is formed on the upper surface of the quartz crystal substrate 200. It should be noted that it is hereinafter assumed that the etching rate of the resist film 500 and the etching rate of the quartz crystal are equal to each other for the sake of convenience of explanation. In the present embodiment, the resist film 500 is formed only on the vibrating part area Q23 of each of the element areas Q2, and the resist film 500 is not formed on the thin-wall part area Q24. In other words, in the thin-wall part area Q24, the upper surface of the quartz crystal substrate 200 is exposed from the resist film 500. Further, a portion overlapping the central portion area Q231 of the resist film 500 is thicker than the separation distance Δd, and a portion overlapping the outer edge portion area Q232 has the thickness gradually decreases from the separation distance Δd to 0 (zero) along a path from the central portion area Q231 toward the thin-wall part area Q24.

### Etching Step S3

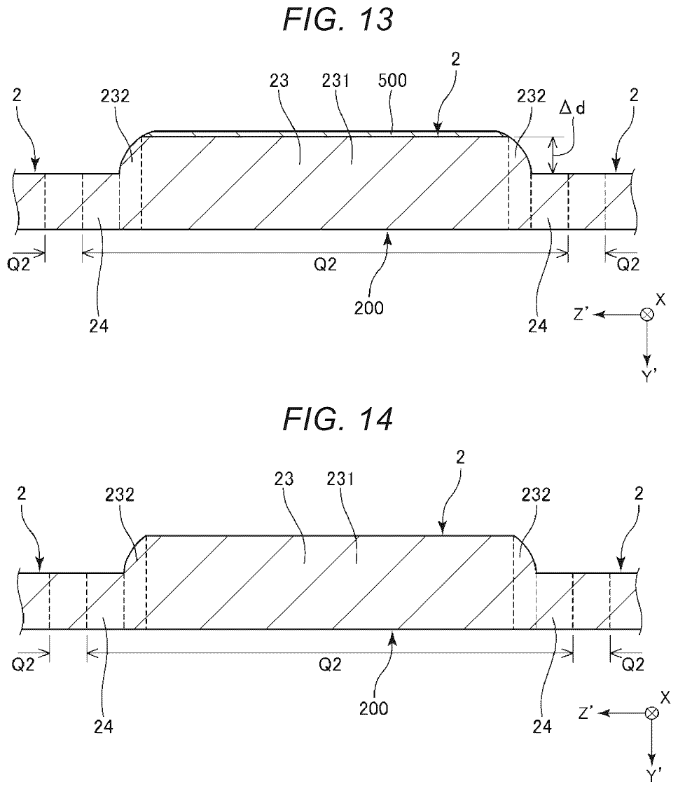

Then, the quartz crystal substrate 200 is dry-etched from the upper surface side of the quartz crystal substrate 200 via the resist film 500. Since the resist film 500 is etched in the same condition as that of the quartz crystal substrate 200, the etching starts as soon as the resist film 500 is removed even in the portion of the quartz crystal substrate 200 overlapping the resist film 500. Therefore, the shape of the resist film 500 is transferred to the upper surface of the quartz crystal substrate 200. The dry etching ends when the shift amount between the upper surface of the vibrating part area Q23 and the upper surface of the thin-wall part area Q24 reaches the separation distance Δd as shown in FIG. 13. Thus, the vibrating part 23 and the thin-wall part 24 are formed in each of the element areas Q2. As described above, due to the dry etching, the thin-wall part 24 can easily be formed. In particular, in the present embodiment, since the resist film 500 is not formed on the thin-wall part area Q24, the etching of the thin-wall part area Q24 starts at the start of the dry etching. Therefore, it is possible to perform the etching step S3 in a shorter time.

It should be noted that in the state in which the dry etching ends, a portion where the original thickness of the resist film 500 is thicker than the separation distance Δd, namely a portion overlapping the central portion area Q231, remains on the quartz crystal substrate 200. Therefore, the central portion area Q231 is protected by the resist film 500, and is not dry-etched. Therefore, even after the dry etching, the upper surface 21 in the vibrating part 23 is kept in the polished surface. Therefore, there is no chance that the upper surface 21 planarized by polishing is roughened by the etching, and accordingly, the surface roughness R1 deteriorates. Therefore, it is possible for the upper surface 21 in the vibrating part 23 to keep the sufficiently low surface roughness R1 even after the dry etching. Further, even after the dry etching, it is possible to keep the vibrating part 23 in the thickness T1. Therefore, it is also possible to suppress the shift in oscillation frequency of the vibrator element 1 due to the dry etching.

### Resist Film Removal Step S4

Subsequently, as shown in FIG. 14, the resist film 500 is removed.

### Contour Formation Step S5

Then, other areas than the quartz crystal substrates 2 of the quartz crystal substrate 200 are removed by dry etching to form the contour of each of the quartz crystal substrates 2 as shown in FIG. 15, and at the same time, a frame 60 and a pair of coupling beams 61, 62 for coupling the frame 60 and the quartz crystal substrates 2 to each other are formed. Thus, there is achieved the state in which the plurality of quartz crystal substrates 2 is integrally formed in the quartz crystal substrate 200.

### Electrode Formation Step S6

Then, the electrodes 3, 4 are formed on each of the quartz crystal substrates 2. Thus, the plurality of vibrator elements 1 is formed in the quartz crystal substrate 200. The method of forming the electrodes 3, 4 is not particularly limited, but the electrodes 3, 4 can be formed by, for example, depositing a metal film on a surface of each of the quartz crystal substrates 2, and then patterning the metal film using a photolithography technique and an etching technique.

### Segmentalization Step S7

Then, each of the vibrator elements 1 is broken off at the coupling beams 61, 62 to thereby be segmentalized. Thus, the plurality of vibrator elements 1 thus segmentalized can be obtained. It should be noted that the method of segmentalizing the vibrator elements 1 is not particularly limited, and it is possible to achieve the segmentalization by, for example, dicing or etching.

The method of manufacturing the vibrator elements 1 is hereinabove described. As described above, the method of manufacturing the vibrator elements 1 is a method of manufacturing the vibrator elements 1 each having the vibrating part 23 making the thickness-shear vibration, and the thin-wall part 24 which is coupled to the vibrating part 23, and which is thinner than the vibrating part 23, and includes the preparation step S1 of preparing the quartz crystal substrate 200, the resist film formation step S2 of forming the resist film 500 in the vibrating part area Q23 of the quartz crystal substrate 200 where the vibrating part 23 is formed, the etching step S3 of etching the quartz crystal substrate 200 via the resist film 500, and then stopping etching in the state in which the resist film 500 remains in the vibrating part area Q23 to thereby form the vibrating part 23 and the thin-wall part 24, and the resist film removal step S4 of removing the resist film 500 remaining.

According to such a manufacturing method, it is possible to suppress the roughening of the upper surface 21 in the vibrating part 23 caused by etching. Therefore, there is no deterioration of the upper surface 21 in the vibrating part 23, and it is possible to suppress an increase and unevenness of the surface roughness R1. Therefore, it becomes difficult for the unwanted vibration to be generated in the vibrating part 23. Further, since the thickness of the vibrating part 23 does not change between before and after the etching, by adjusting the thickness of the vibrating part 23 before the etching in advance, it is possible to obtain the vibrator element 1 having a predetermined oscillation frequency. Further, according to etching, it is possible to easily and accurately form the thin-wall part 24. As described above, according to the manufacturing method of the present embodiment, the vibrator element 1 having excellent vibration characteristics can easily be manufactured.

Further, as described above, in the manufacturing method described above, there is included the electrode formation step S6 of forming the electrodes 3, 4 in the vibrating part 23 after the resist film removal step S4. Thus, the electrodes 3, 4 can easily be formed.

Further, as described above, in the manufacturing method described above, in the resist film formation step S2, the resist film 500 is not formed in the thin-wall part area Q24 of the quartz crystal substrate 200 where the thin-wall part 24 is formed. Thus, the etching of the thin-wall part area Q24 is started at the start of the etching. Therefore, it is possible to perform the etching step in a shorter time.

Further, as described above, in the manufacturing step described above, the resist film formation step S2 includes the coating step S21 of applying the resist material 5 to the quartz crystal substrate 200, the exposure step S22 of exposing the resist material 5, and the development step S23 of developing the resist material 5. Thus, the resist film 500 can easily be formed.

Further, as described above, in the manufacturing method described above, the upper surface 21 as the surface in the vibrating part area Q23 of the quartz crystal substrate 200 prepared in the preparation step S1 is a polished surface. Thus, it is possible to form the upper surface 21 higher in flatness. Therefore, it becomes more difficult for the unwanted vibration to be generated in the vibrating part 23.

### Second Embodiment

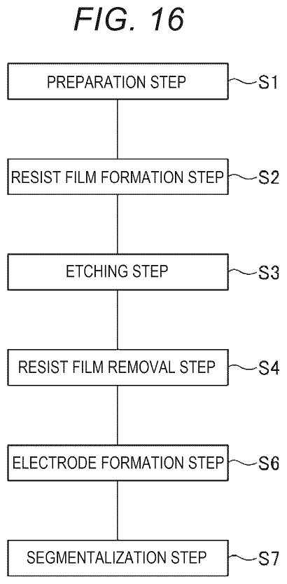

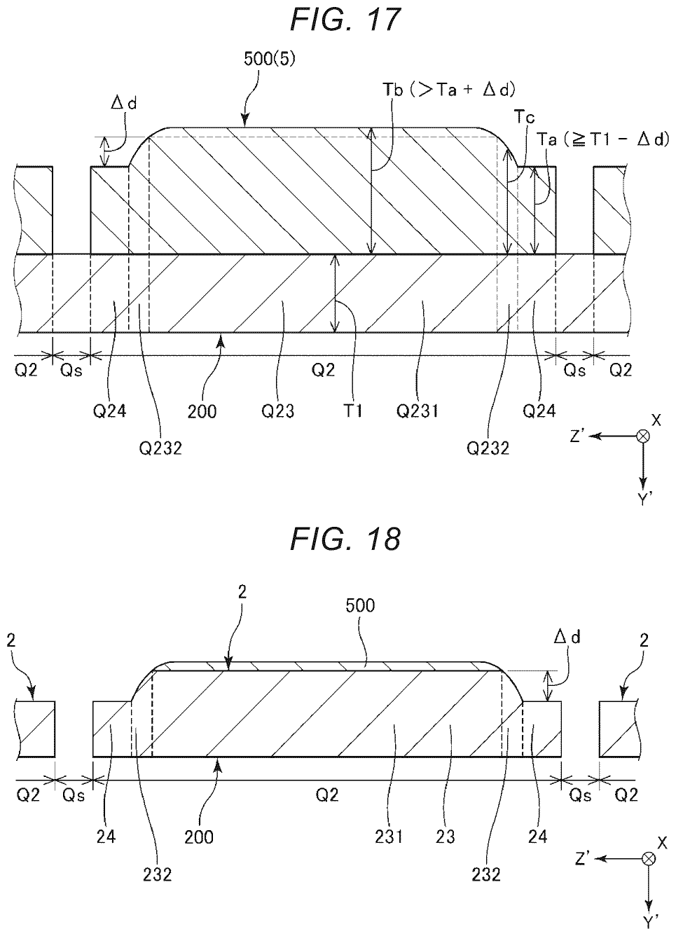

FIG. 16 is a flowchart showing a manufacturing process of a vibrator element according to a second embodiment of the present disclosure. FIG. 17 and FIG. 18 are each a cross-sectional view for explaining a method of manufacturing the vibrator elements.

The vibrator element 1 according to the present embodiment is substantially the same as the vibrator element 1 according to the first embodiment described above except the point that the manufacturing method is different. It should be noted that in the following description, the method of manufacturing the vibrator element 1 according to the second embodiment will be described with a focus on the difference from the first embodiment described above, and the description of substantially the same issues will be omitted. Further, in FIG. 16 through FIG. 18, the constituents substantially the same as those of the embodiment described above are denoted by the same reference symbols.

As shown in FIG. 16, the method of manufacturing the vibrator element 1 according to the present embodiment includes the preparation step S1 of preparing the quartz crystal substrate 200, the resist film formation step S2 of forming the resist film 500 on the quartz crystal substrate 200, the etching step S3 of etching the quartz crystal substrate 200 via the resist film 500 to form the quartz crystal substrates 2, the resist film removal step S4 of removing the resist film 500 remaining, the electrode formation step S6 of providing the quartz crystal substrate 2 with the electrodes 3, 4, and the segmentalization step S7 of segmentalizing the vibrator element 1.

In the present embodiment, the contour formation step S5 in the first embodiment described above is performed at the same time as the etching step S3. It should be noted that since the preparation step S1, the resist film removal step S4, the electrode formation step S6, and the segmentalization step S7 are substantially the same as those in the first embodiment described above, only the resist film formation 2 and the etching step S3 will hereinafter be described.

### Resist Film Formation Step S2

First, as shown in FIG. 17, the resist film 500 made of the resist material 5 is formed on the upper surface of the quartz crystal substrate 200. It should be noted that it is hereinafter assumed that the etching rate of the resist film 500 and the etching rate of the quartz crystal are equal to each other similarly to the first embodiment described above. In the present embodiment, the resist film 500 is formed in the entire area of each of the element areas Q2. A thickness Ta of a portion of the resist film 500 overlapping the thin-wall part area Q24 is no smaller than T1−Δd, a thickness Tb of a portion overlapping the central portion area Q231 is thicker than Ta+Δd, and a thickness Tc of a portion overlapping the outer edge portion area Q232 gradually decreases from Ta+Δd to Ta along a path from the central portion area Q231 toward the thin-wall part area Q24.

It should be noted that although not shown in the drawings, in an area Qs between the pair of element areas Q2 adjacent to each other, the resist film 500 having a desired thickness is formed so that the frame 60 and the coupling beams 61, 62 are formed in the etching step S3 to be performed later.

### Etching Step S3

Then, the quartz crystal substrate 200 is dry-etched from the upper surface side of the quartz crystal substrate 200 via the resist film 500. Then, the dry etching is terminated when the shift amount between the upper surface of the vibrating part area Q23 and the upper surface of the thin-wall part area Q24 reaches the separation distance Δd as shown in FIG. 18. Thus, the vibrating part 23 and the thin-wall part 24 are formed in each of the element areas Q2. Further, in the area Qs, the quartz crystal substrate 200 is dug forward until the quartz crystal substrate 200 is penetrated. Therefore, the contour of each of the quartz crystal substrates 2 is formed, and at the same time, the frame 60 and the pair of coupling beams 61, 62 for coupling the frame 60 the quartz crystal substrates 2 to each other are formed although not shown. Thus, there is achieved the state in which the plurality of quartz crystal substrates 2 is integrally formed in the quartz crystal substrate 200. As described above, according to the present embodiment, since the outer shape of the quartz crystal substrate 2 can be formed by the single dry etching, it is possible to achieve simplification of the manufacturing process of the vibrator element 1 compared to the first embodiment described above.

It should be noted that in the state in which the dry etching ends, there is created a state in which the portion where the original thickness of the resist film 500 is thicker than Ta+Δd, namely the portion overlapping the central portion area Q231, remains on the quartz crystal substrate 200. Therefore, the central portion area Q231 is protected by the resist film 500, and is not dry-etched. Therefore, the upper surface 21 in the vibrating part 23 can be kept in the polished surface even after the dry etching. Therefore, there is no chance that the upper surface 21 which has once been planarized (mirrored) by polishing with an effort is roughened by the etching, and accordingly, the surface roughness R1 deteriorates. Therefore, even after the etching, it is possible to maintain the surface roughness R1 sufficiently low. Further, even after the etching, it is possible to keep the vibrating part 23 in the thickness T1. Therefore, it is also possible to suppress the shift in oscillation frequency due to the etching.

As described hereinabove, in the method of manufacturing the vibrator element 1 according to the present embodiment, the resist film 500 is formed in the thin-wall part area Q24 of the quartz crystal substrate 200 where the thin-wall part 24 is formed with a smaller thickness than that of the portion located in the vibrating part area Q23 in the resist film formation step S2. Thus, it is possible to form the outer shape of the quartz crystal substrate 200 by performing the single etching step S3. Therefore, it is possible to achieve the simplification of the manufacturing process of the vibrator element 1 compared to the first embodiment described above.

According also to such a second embodiment, there can be exerted substantially the same advantages as in the first embodiment described above.

### Third Embodiment

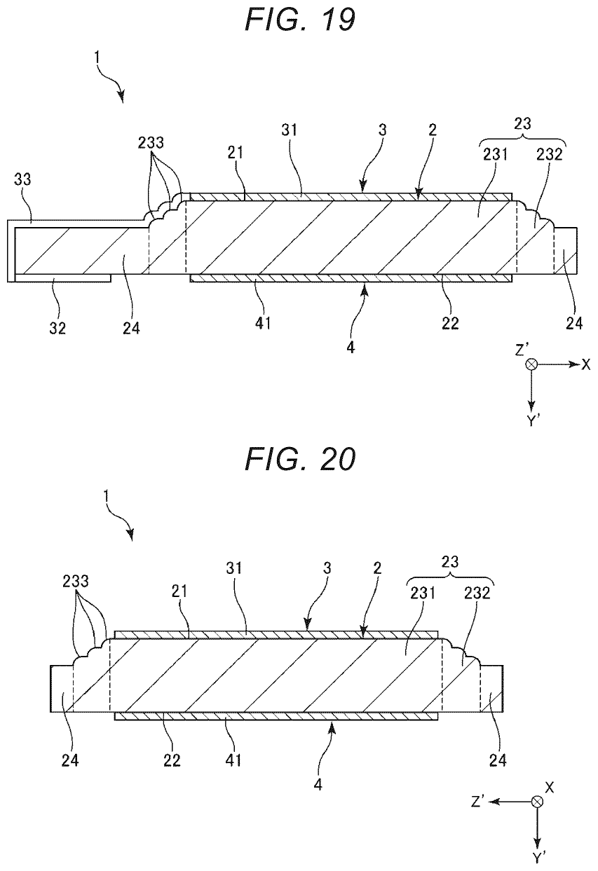

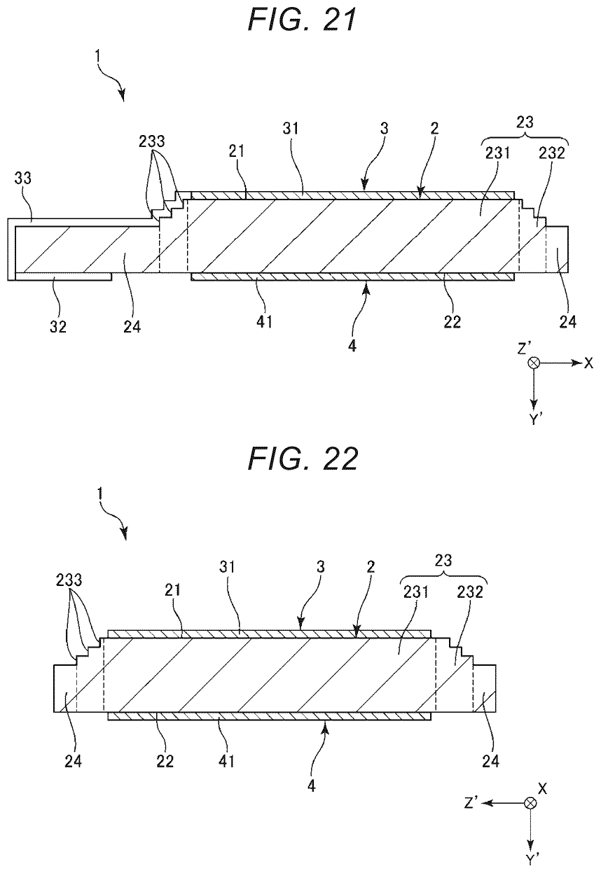

FIG. 19 and FIG. 20 are cross-sectional views showing a vibrator element according to a third embodiment of the present disclosure. FIG. 21 and FIG. 22 are cross-sectional views showing a modified example of the vibrator element. It should be noted that FIG. 19 and FIG. 21 are the cross-sectional views each corresponding to the cross-sectional view along the line A-A in FIG. 1, and FIG. 20 and FIG. 22 are the cross-sectional views each corresponding to the cross-sectional view along the line B-B in FIG. 1.

The vibrator element 1 according to the present embodiment is substantially the same as the vibrator element 1 according to the first embodiment described above except the point that the configuration of the vibrating part 23 is different. It should be noted that in the following description, the vibrator element 1 according to the third embodiment will be described with a focus on the difference from the first embodiment described above, and the description of substantially the same issues will be omitted. Further, in FIG. 19 through FIG. 22, the constituents substantially the same as those of the embodiments described above are denoted by the same reference symbols.

As shown in FIG. 19 and FIG. 20, in the vibrator element 1 according to the present embodiment, the outer edge portion 232 of the vibrating part 23 has a plurality of steps 233. In the present embodiment, there are formed the three steps 233. By providing the outer edge portion 232 with such a configuration, it is possible to effectively confine the thickness-shear vibration in the vibrating part 23 similarly to the first embodiment described above. Therefore, there is obtained the vibrator element 1 in which the vibration leakage is suppressed, and which has the excellent vibration characteristics. Further, since each of the steps 233 becomes smaller compared to the first embodiment described above, the coverage of the metal film to be the base material of the electrodes 3, 4 when depositing the metal film is improved, and it is possible to suppress the broken line of the first coupling interconnection 33 on the outer edge portion 232.

It should be noted that the number of the steps 233 is not limited to three, and can be two, or can also be four or more. Further, the shape of each of the steps 233 is not particularly limited, and can be, for example, a rectangular shape as shown in FIG. 21 and FIG. 22. Further, at least one of the steps 233 can have a different shape from those of the rest of the steps 233.

As described above, in the vibrator element 1 according to the present embodiment, the outer edge portion 232 of the vibrating part 23 has the plurality of steps 233. Thus, it is possible to effectively confine the thickness-shear vibration in the vibrating part 23. Therefore, there is obtained the vibrator element 1 in which the vibration leakage is suppressed, and which has the excellent vibration characteristics.

According also to such a third embodiment, substantially the same advantages as in the first embodiment described above can be exerted.

### Fourth Embodiment

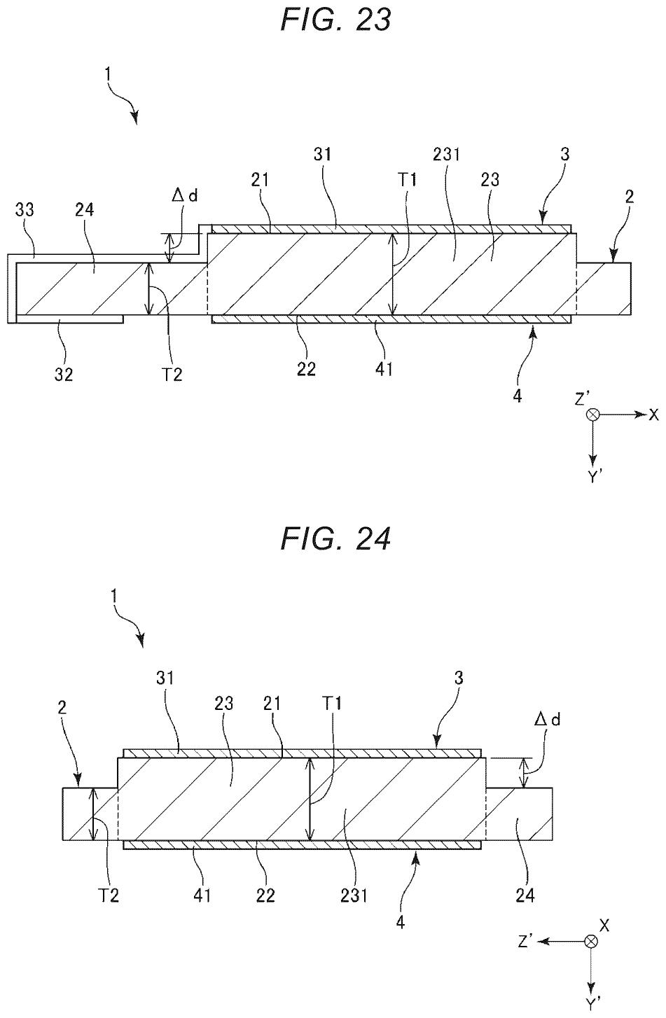

FIG. 23 and FIG. 24 are cross-sectional views showing a vibrator element according to a fourth embodiment of the present disclosure. FIG. 25 through FIG. 27 are cross-sectional views for explaining a method of manufacturing the vibrator elements. It should be noted that FIG. 23 is the cross-sectional view corresponding to the cross-sectional view along the line A-A in FIG. 1, and FIG. 24 is the cross-sectional view corresponding to the cross-sectional view along the line B-B in FIG. 1.

The vibrator element 1 according to the present embodiment is substantially the same as the vibrator element 1 according to the first embodiment described above except the point that the configuration of the vibrating part 23 is different. It should be noted that in the following description, the vibrator element 1 according to the fourth embodiment will be described with a focus on the difference from the first embodiment described above, and the description of substantially the same issues will be omitted. Further, in FIG. 23 through FIG. 27, the constituents substantially the same as those of the embodiments described above are denoted by the same reference symbols.

As shown in FIG. 23 and FIG. 24, in the vibrator element 1 according to the present embodiment, the outer edge portion 232 of the vibrating part 23 is omitted, and the side surface of the vibrating part 23 is perpendicular to the upper surface 21.

Similarly to the first embodiment described above, the method of manufacturing the vibrator element 1 according to the present embodiment includes the preparation step S1 of preparing the quartz crystal substrate 200, the resist film formation step S2 of forming the resist film 500 on the quartz crystal substrate 200, the etching step S3 of etching the quartz crystal substrate 200 via the resist film 500 to form the vibrating part 23 and the thin-wall part 24, the resist film removal step S4 of removing the resist film 500 remaining on the quartz crystal substrate 200, the contour formation step S5 of forming the contour of the quartz crystal substrate 2, the electrode formation step S6 of providing the quartz crystal substrate 2 with the electrodes 3, 4, and the segmentalization step S7 of segmentalizing the vibrator element 1.

It should be noted that since the preparation step S1, the resist film removal step S4, the contour formation step S5, the electrode formation step S6, and the segmentalization step S7 are substantially the same as those in the first embodiment described above, only the resist film formation step S2 and the etching step S3 will hereinafter be described.

### Resist Film Formation Step S2

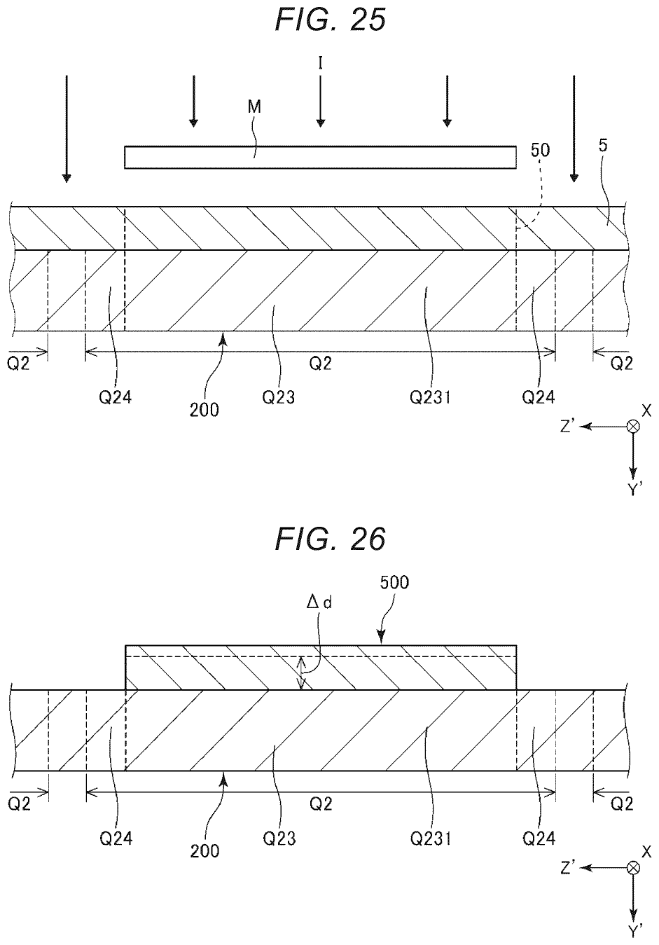

First, as shown in FIG. 25, the resist material 5 is applied to the upper surface of the quartz crystal substrate 200 with a predetermined thickness. Then, each of the element areas Q2 is irradiated with the electromagnetic wave I the exposure intensity of which is constant via a mask M to thereby form the exposure boundary areas 50 due to presence or absence of the exposure in the resist material 5. Subsequently, the resist material 5 is developed. Thus, as shown in FIG. 26, the resist film 500 made of the resist material 5 is formed on the upper surface of the quartz crystal substrate 200.

### Etching Step S3

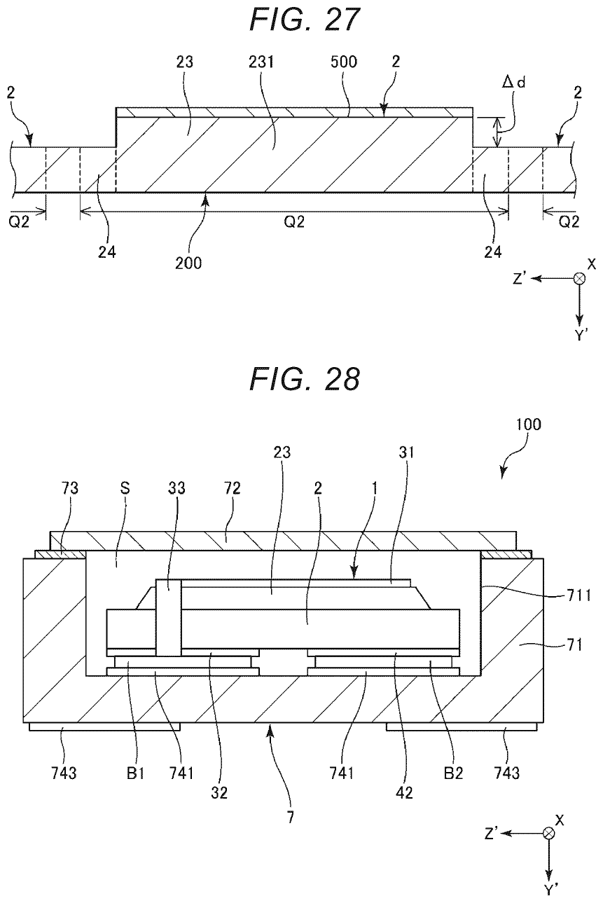

Then, the quartz crystal substrate 200 is dry-etched from the upper surface side of the quartz crystal substrate 200 via the resist film 500. Then, the dry etching is terminated when the shift amount between the upper surface of the vibrating part area Q23 and the upper surface of the thin-wall part area Q24 reaches the separation distance Δd as shown in FIG. 27. Thus, there is achieved the state in which the vibrating part 23 and the thin-wall part 24 are formed in each of the element areas Q2.

According also to such a fourth embodiment, substantially the same advantages as in the first embodiment described above can be exerted.

### Fifth Embodiment

FIG. 28 is a cross-sectional view showing a vibrator according to a fifth embodiment of the present disclosure.

As shown in FIG. 28, a vibrator 100 has the vibrator element 1 and a package 7 for housing the vibrator element 1. Further, the package 7 has a base 71 provided with a recessed part 711 opening in an upper surface, and a lid 72 which is bonded to an upper surface of the base 71 via a bonding member 73 so as to close the opening of the recessed part 711, and which shaped like a plate. The recessed part 711 forms an internal space S inside the package 7, and the vibrator element 1 is housed in the internal space S. For example, the base 71 is formed of ceramics such as alumina, and the lid 72 is formed of a metal material such as Kovar. It should be noted that the package 7 is not particularly limited providing the package 7 can house the vibrator element 1 inside. Further, the constituent materials of the base 71 and the lid 72 are not particularly limited.

The internal space S is airtightly sealed, and is set in a reduced-pressure state, and preferably, in a state approximate to a vacuum state. Thus, the vibration characteristics of the vibrator element 1 are improved. It should be noted that the atmosphere in the internal space S is not particularly limited, and can be an atmosphere filled with an inert gas such as nitrogen or Ar, or can also be in the atmospheric pressure state or a pressurized state instead of the reduced-pressure state.

Further, a pair of internal terminals 741 are disposed on a bottom surface of the recessed part 711, and a pair of external terminals 743 are disposed on a lower surface of the base 71. The internal terminals 741 are electrically coupled to the corresponding external terminals 743 via interconnections not shown formed in the base 71, respectively. Further, one of the internal terminals 741 is electrically coupled to the first terminal 32 of the vibrator element 1 via a bonding member B1 having electrical conductivity, and the other of the internal terminals 741 is electrically coupled to the second terminal 42 of the vibrator element 1 via a bonding member B2 having electrical conductivity.

As described above, the vibrator 100 has the vibrator element 1 and the package 7 for housing the vibrator element 1. Therefore, it is possible to appreciate the advantages of the vibrator element 1 described above, and there is obtained the vibrator 100 having high reliability.

The vibrator element 1 is used as an oscillator 1 in combination with, for example, an oscillation circuit, and can be installed in a smartphone, a personal computer, a digital still camera, a tablet terminal, a timepiece, a smart watch, an inkjet printer, a television set, a wearable terminal such as a pair of smart glasses or an HMD (head-mounted display), a video camera, a video cassette recorder, a car navigation system, a drive recorder, a personal digital assistance, an electronic dictionary, an electronic translator, an electronic calculator, a computerized game machine, a toy, a word processor, a workstation, a video phone, a security video monitor, electronic binoculars, a POS terminal, medical equipment, a fish finder, a variety of measurement instruments, equipment for a mobile terminal base station, a variety of gauges for a vehicle, a railroad vehicle, an airplane, a helicopter, a ship, or a boat, a flight simulator, a variety of types of electronic equipment such as a network server, a variety of vehicles such as a car, a robot, a drone, a motorcycle, an airplane, a ship, a boat, an electric train, a rocket, and a space ship.

Although the method of manufacturing the vibrator element, the vibrator element, and the vibrator according to the present disclosure are hereinabove described based on the illustrated embodiments, the present disclosure is not limited to the embodiments, but the constituents of each of the components can be replaced with those having substantially the same function and an arbitrary configuration. Further, the present disclosure can also be added with any other constituents. Further, the present disclosure can be a combination of any two or more configurations of the embodiments described above.

Further, although the quartz crystal substrate 2 has the mesa type structure in which the vibrating part 23 projects only at the upper surface 21 side in the embodiments described above, this is not a limitation, and it is possible to adopt the mesa type structure in which the vibrating part 23 projects at both of the upper surface 21 side and the lower surface 22 side. In this case, it is sufficient to perform the resist film formation step S2 and the etching step S3 with respect to the lower surface 22 side similarly to the upper surface 21 side. Further, it is also possible to perform a bevel treatment for grinding the periphery of the quartz crystal substrate 2 to thereby chamfer the quartz crystal substrate 2, or a convex treatment for changing the upper surface 21 and the lower surface 22 to a convex surface.

What is claimed is:

1. A method of manufacturing a vibrator element having a vibrating part which vibrates in a thickness-shear mode, and a thin-wall part which is coupled to the vibrating part, and which is thinner than the vibrating part, the method comprising:
a preparation step of preparing a quartz crystal substrate;
a resist film formation step of forming a resist film in a vibrating part area of the quartz crystal substrate where the vibrating part is formed;
an etching step of etching the quartz crystal substrate via the resist film, then ending the etching in a state in which the resist film remains in the vibrating part area to thereby form the vibrating part and the thin-wall part; and
a resist film removal step of removing the resist film remaining.

2. The method according to claim 1, further comprising:
an electrode formation step of forming an electrode in the vibrating part after the resist film removal step.

3. The method according to claim 1, wherein
in the resist film formation step, the resist film is not formed in a thin-wall part area of the quartz crystal substrate where the thin-wall part is formed.

4. The method according to claim 1, wherein
in the resist film formation step, the resist film is formed in a thin-wall part area of the quartz crystal substrate where the thin-wall part is formed so that the resist film is thinner than a portion of the resist film located in the vibrating part area.

5. The method according to claim 1, wherein
the resist film formation step includes
a coating step of applying a resist material to the quartz crystal substrate,
an exposure step of exposing the resist material, and
a development step of developing the resist material.

6. The method according to claim 1, wherein
a surface of the vibrating part area of the quartz crystal substrate prepared in the preparation step is a polished surface.
